(19) United States
(12) Patent Application Publication
(10) Pub. No.: US 2012/0025405 A1
(43) Pub. Date: Feb. 2, 2012

(54) LIQUID ENCAPSULATING RESIN COMPOSITION, SEMICONDUCTOR DEVICE USING LIQUID ENCAPSULATING RESIN COMPOSITION, AND METHOD OF MANUFACTURING THE SAME

(76) Inventor: Hiroshi Ito, Tokyo (JP)

(21) Appl. No.: 13/259,056

(22) PCT Filed: Jan. 28, 2010
(86) PCT No.: PCT/JP2010/000495

§ 371 Date: Sep. 22, 2011

(30) Foreign Application Priority Data
Apr. 10, 2009 (JP) 2009-095382

(51) Int. Cl. H01L 23/29; C09D 163/00; H01L 21/56

(52) U.S. Cl. 257/788; 438/124; 523/400; 257/E21.502; 257/E23.117

(57) ABSTRACT

Disclosed is a liquid encapsulating resin composition containing an epoxy resin (A), an amine type curing agent (B), and a basic compound (C), wherein, in case that the liquid encapsulating resin composition is filled between a semiconductor element and a substrate connected to each other by solder bumps, the residue of a fluxing agent used for forming the solder bump connection is removed.

### TECHNICAL FIELD

The present invention relates to a liquid encapsulating resin composition, a semiconductor device using the liquid encapsulating resin composition and a method of manufacturing the liquid encapsulating resin composition.

### BACKGROUND ART

In a flip-chip type semiconductor device, a semiconductor element and a substrate are electrically connected by solder bumps. In the flip-chip type semiconductor device, in order to improve connection reliability, a liquid encapsulating resin composition which is called an underfill material is filled between the semiconductor element and the substrate to reinforce the periphery of the solder bumps.

Such a flip-chip type semiconductor device is generally manufactured by a step of applying a fluxing agent onto solder bumps of a semiconductor element having solder bumps, a step of temporarily placing fluxing agent-applied solder bumps on a substrate, a step (solder reflow) of soldering the substrate and the semiconductor element, a step of washing the fluxing agent and a step of applying an underfill material to fill between the semiconductor element and the substrate.

The fluxing agent has been widely used for surely carrying out solder connection by removing an oxide coating formed on the surface of the solder bumps, but the fluxing agent needs to be removed after the solder connection because the fluxing agent causes formation of ionic impurities and outgassing. Then, as a fluxing agent, there has been proposed a fluxing agent such as a solvent wash type fluxing agent, a water wash type fluxing agent or the like (for example, see Patent Document 1).

### RELATED DOCUMENT

Patent Document 1: Japanese Laid-open Patent Publication No. 2000-42786

### DISCLOSURE OF THE INVENTION

However, a fluxing agent might not be fully removed even with washing of the fluxing agent by such solvent washing or water washing, and the fluxing agent might remain on the periphery of solder bumps as the residue in some cases.

When such a residue of the fluxing agent is present on the periphery of solder bumps, there are defects such that an underfill material is deteriorated due to the residue, an underfill material is not fully filled on the periphery and the like, so that strength is not sufficient for peeling off the bumps due to external force such as vibration, thermal shock or the like, and conduction is not obtained, or moisture penetrates into such portions so that bump metals are corroded and migration is caused. Thus, the reliability of the semiconductor device is lowered in some cases.

Meanwhile, by the use of a fluxing agent which does not require washing, generally called a no-wash fluxing agent, a semiconductor device is sometimes assembled. However, in this case, washing is not conducted, so that the reliability is lowered, because of the above-mentioned reasons in some cases.

The present invention has been accomplished in view of the above circumstances. An object of the present invention is to achieve a liquid encapsulating resin composition which improves the reliability of a semiconductor device by reducing the residue of a fluxing agent in a semiconductor device manufactured through a step of using a fluxing agent when a semiconductor element and a substrate are connected by solder bumps.

The object is achieved by the present invention as specified by the matters described in the following (1) to (10).

(1) A liquid encapsulating resin composition containing an epoxy resin (A), an amine type curing agent (B) and a basic compound (C), wherein, in case that the liquid encapsulating resin composition is filled between a semiconductor element and a substrate connected to each other by solder bumps, the residue of a fluxing agent used for forming the solder bump connection is removed.

(2) The liquid encapsulating resin composition according to (1), wherein the pH value of the liquid encapsulating resin composition is greater than 7.

(3) The liquid encapsulating resin composition according to (1) or (2), wherein the basic compound (C) is at least one kind among 1,8-diazabicyclo(5.4.0)undecene-7,1,5-diazabicyclo(4.3.0)nonene-5 and a salt thereof.

(4) The liquid encapsulating resin composition according to any one of (1) to (3), wherein the content of the basic compound (C) is equal to or more than 0.005% by weight and equal to or less than 0.3% by weight, based on the total amount of the liquid encapsulating resin composition.

(5) The liquid encapsulating resin composition according to any one of (1) to (4), wherein the basic compound (C) and the amine type curing agent (B) are mixed in advance, and then the epoxy resin (A) is mixed thereto.

(6) The liquid encapsulating resin composition according to any one of (1) to (4), wherein the basic compound (C) and the epoxy resin (A) are mixed in advance, and then the amine type curing agent (B) is mixed thereto.

(7) The liquid encapsulating resin composition according to any one of (1) to (6), wherein the residue of the fluxing agent is mainly composed of a carboxylic acid or a carboxylic acid derivative.

(9) A semiconductor device, wherein a gap between the aforementioned semiconductor element and the substrate is encapsulated with a cured product of the liquid encapsulating resin composition according to any one of (1) to (7).

(10) A method of manufacturing a semiconductor device comprising:

applying a fluxing agent onto solder bumps arranged in a semiconductor element or other body for temporarily connecting the semiconductor element and the other body;

soldering the temporarily connected semiconductor element and the other body through the solder reflow; and

applying the liquid encapsulating resin composition according to any one of (1) to (7) to fill between the semiconductor element and the other body.

According to the present invention, it is possible to achieve a liquid encapsulating resin composition which improves the reliability of a semiconductor device by reducing the residue of a fluxing agent in a semiconductor device manufactured through a step of using a fluxing agent when a semiconductor element and a substrate are connected by solder bumps, and a semiconductor device using the liquid encapsulating resin composition.

### DESCRIPTION OF EMBODIMENTS

Hereinafter, the liquid encapsulating resin composition and the semiconductor device of the present invention will be described.

First, the liquid encapsulating resin composition will be described.

The liquid encapsulating resin composition of the present invention is used for a semiconductor device which is manufactured through a step of using a fluxing agent when a semiconductor element and a substrate are connected by solder bumps. When the residue of the fluxing agent is formed during the manufacture of the semiconductor device, the residue of the fluxing agent may be removed and the semiconductor device may be encapsulated, by using the liquid encapsulating resin composition. Furthermore, even when a no-wash fluxing agent is used, the liquid encapsulating resin composition is used to suppress deterioration of the reliability caused by the residue of the no-wash fluxing agent remained on the periphery of the solder bumps.

The liquid encapsulating resin composition of the present invention contains an epoxy resin (A). Accordingly, the cured product of encapsulating resin composition is excellent in heat resistance, moisture resistance and mechanical strength, while the semiconductor element is firmly attached to the substrate. Thus, a semiconductor device excellent in the reliability can be obtained.

As the epoxy resin (A), the molecular weight and structure are not particularly limited so long as the resin contains two or more epoxy groups in the molecule. Examples include novolac type epoxy resins such as a phenol novolac type epoxy resin, a cresol novolac type epoxy resin and the like; bisphenol type epoxy resins such as a bisphenol A type epoxy resin, a bisphenol F type epoxy resin and the like; aromatic glycidyl amine type epoxy resins such as N,N-diglycidylaniline, N,N-diglycidyltoluidine, diaminodiphenylmethane type glycidyl amine, aminophenol type glycidyl amine and the like; epoxy resins such as a hydroquinone type epoxy resin, a biphenyl type epoxy resin, a stilbene type epoxy resin, a triphenolmethane type epoxy resin, a triphenolpropane type epoxy resin, an alkyl-modified triphenolmethane type epoxy resin, a triazine nucleus-containing epoxy resin, a dicyclopentadiene-modified phenol type epoxy resin, a naphthol type epoxy resin, a naphthalene type epoxy resin, aralkyl type epoxy resins such as a phenol aralkyl type epoxy resin having a phenylene skeleton and/or a biphenylene skeleton, a naphthol aralkyl type epoxy resin having a phenylene skeleton and/or a biphenylene skeleton and the like; and aliphatic epoxy resins such as alicyclic epoxy including vinylcyclohexene dioxide, dicyclopentadiene oxide, alicyclic diepoxy-adipate and the like.

Further, in the present invention, an epoxy resin having a glycidyl structure or a glycidyl amine structure bonded to an aromatic ring is more preferable from the viewpoints of heat resistance, mechanical characteristics and moisture resistance. The amount of the aliphatic epoxy resin and the alicyclic epoxy resin in use is further preferably limited from the viewpoint of the reliability, particularly adhesion. These may be used singly or may be used in combination of two or more kinds. In the present invention, because of the aspect of the liquid encapsulating resin composition, the epoxy resin (A) is preferably liquid at normal temperature (25 degrees centigrade) at last, and although the epoxy resin is solid at normal temperature, the solid epoxy resin may be in a liquid state at last by being dissolved in an epoxy resin which is liquid at normal temperature.

The content of the epoxy resin (A) is not particularly limited, but it is preferably equal to or more than 5% by weight and equal to or less than 50% by weight, and particularly preferably equal to or more than 10% by weight and equal to or less than 40% by weight, based on the total amount of the liquid encapsulating resin composition. In case that, the content is within the aforementioned range, the reactivity, heat resistance and mechanical strength of the composition, and fluidity characteristics during encapsulating are excellent.

The liquid encapsulating resin composition of the present invention contains an amine type curing agent (B). Accordingly, the epoxy resin (A) is cured.

As the amine type curing agent (B), the molecular weight and structure are not particularly limited so long as the agent contains two or more primary amines or secondary amines capable of forming a covalent bond with an epoxy group in the epoxy resin (A) in the molecule.

Examples of the amine type curing agent (B) include aliphatic polyamines such as diethylenetriamine, triethylenetetramine, tetraethylenepentamine, m-xylenediamine, trimethylhexamethylenediamine and 2-methylpentamethylenediamin; alicyclic polyamines such as isophoronediamine, 1,3-bisaminomethylcyclohexane, bis(4-aminocyclohexyl)methane, norbornenediamine, 1,2-diaminocyclohexane and the like; piperazine polyamines such as N-aminoethyl piperazine, 1,4-bis(2-amino-2-methylpropyl) piperazine and the like; and aromatic polyamines such as diaminodiphenylmethane, m-phenylenediamine, diaminodiphenylsulfone, diethyltoluenediamine, trimethylenebis(4-aminobenzoate), polytetramethylene oxide-di-P-aminobenzoate and the like.

These amine type curing agents (B) may be used singly or two or more curing agents may be combined. Furthermore, when encapsulating purpose of the semiconductor device is considered, further preferably used is an aromatic polyamine type curing agent from the viewpoints of heat resistance, electrical properties, mechanical properties, adhesion and moisture resistance. When the aspect of the present invention is based on a liquid encapsulating resin composition used as an underfill, the amine type curing agent is more preferably a liquid at room temperature (25 degrees centigrade).

The content of the amine type curing agent (B) is not particularly limited, but it is preferably equal to or more than 5% by weight and equal to or less than 50% by weight, and particularly preferably equal to or more than 10% by weight and equal to or less than 40% by weight, based on the total amount of the liquid encapsulating resin composition. In case that, the content is within the aforementioned range, the reactivity, and mechanical properties and heat resistance of the composition are excellent.

Meanwhile, the active hydrogen equivalent weight of the amine type curing agent (B) to the epoxy equivalent of the epoxy resin (A) is preferably equal to or more than 0.6 and equal to or less than 1.4, and particularly preferably equal to or more than 0.7 and equal to or less than 1.3. In case that, the active hydrogen equivalent weight of the amine type curing agent (B) is within the aforementioned range, the reactivity and heat resistance of the resin composition are particularly improved.

The liquid encapsulating resin composition of the present invention contains a basic compound (C). Accordingly, it is possible to remove the residue of the fluxing agent. Furthermore, the pH value of the liquid encapsulating resin composition may be greater than 7 with the use of the basic compound (C).

Examples of the basic compound (C) include various amine compounds such as iminodiethanol, ethylaminoethanol, isopropylaminoethanol, isopropylbenzylamine, dibutylaminoethanol, isopropanolamine, dibutylamine, dioctylamine, aminoethoxyethanol and the like. Among these, examples include 1,8-diazabicyclo(5.4.0) undecene-7,1,5-diazabicyclo(4.3.0)nonene-5, and a salt thereof. When at least one kind among these compounds is used, it is further preferable because the flowability and storage stability become excellent.

The content of the basic compound (C) is particularly preferably equal to or more than 0.005% by weight and equal to or less than 0.01% by weight, based on the total amount of the liquid encapsulating resin composition. Accordingly, the flowability of the liquid encapsulating resin composition becomes excellent, and the flowability and removal performance of the fluxing agent residue are well balanced. On the other hand, the content of the basic compound (C) is preferably equal to or less than 0.3% by weight and particularly more preferably equal to or less than 0.2% by weight, based on the total amount of the liquid encapsulating resin composition. Accordingly, removal performance of the fluxing agent residue becomes excellent, and the flowability and removal performance of the fluxing agent residue are well balanced.

A method of mixing these components is not particularly limited, but preferably used is a method of mixing the amine type curing agent (B) with the basic compound (C) in advance, and then mixing the epoxy resin (A) thereto. Accordingly, an effect of improving the flowability when the epoxy resin (A) is mixed may be particularly increased.

Or, the epoxy resin (A) and the basic compound (C) may be mixed in advance, and then the amine type curing agent (B) may be mixed thereto. Accordingly, since the basic compound (C) acts on the epoxy resin (A) prior to the amine type curing agent (B), an effect of suppressing deterioration of a liquid encapsulating resin composition containing the epoxy resin (A) and the amine type curing agent (B) due to the residue of the fluxing agent is further improved.

Incidentally, mixing in advance means, for example, stirring at room temperature for 30 minutes, and then allowing to stand for 30 minutes or longer. The upper limit of the time involved in allowing to stand is not particularly limited, but the mixture is preferably allowed to stand overnight from the viewpoint of workability or the like.

Furthermore, the liquid encapsulating resin composition of the present invention may contain an inorganic filler. Mechanical strength such as fracture toughness or the like, high temperature dimensional stability and moisture resistance may be improved, so that the reliability of the semiconductor device using the liquid encapsulating resin composition containing the inorganic filler may be particularly improved.

Examples of the inorganic filler include silicate such as talc, calcined clay, uncalcined clay, mica, glass and the like; oxide of silica powder such as titanium oxide, alumina, fused silica (spherical fused silica, crushed fused silica), synthetic silica, crystalline silica and the like; carbonate such as calcium carbonate, magnesium carbonate, hydrotalcite and the like; hydroxide such as aluminum hydroxide, magnesium hydroxide, calcium hydroxide and the like; sulfate and sulfite such as barium sulfate, calcium sulfate, calcium sulfite and the like; borate such as zinc borate, barium metaborate, aluminum borate, calcium borate, sodium borate and the like; and nitride such as aluminum nitride, boron nitride, silicon nitride and the like. Of these fillers, preferably used are fused silica, crystalline silica and synthetic silica powder from the viewpoint of improvement of heat resistance, moisture resistance, strength and the like of the resin composition.

These inorganic fillers may be used singly or in mixture. The shape of the inorganic filler is not particularly limited, but the shape is preferably spherical in view of viscosity and fluidity characteristics.

When a liquid encapsulating resin composition containing an inorganic filler is used for a semiconductor device, the average particle size of the inorganic filler is not particularly limited, but it is particularly preferably equal to or more than 0.1 μm, and more preferably equal to or more than 0.2 μm. Accordingly, an effect of suitably lowering the viscosity of the resin composition and improving the flowability is increased. Furthermore, the average particle size of the inorganic filler is particularly preferably equal to or less than 30 μm, and more preferably equal to or less than 8 μm. Accordingly, in case that, the liquid encapsulating resin composition flows into a semiconductor device, an effect of suppressing partial unfilling or insufficient filling due to clogging of a filler is increased.

In case that, the liquid encapsulating resin composition containing an inorganic filler is used for a semiconductor device, the content of the inorganic filler is not particularly limited, but it is particularly preferably equal to or more than 30% by weight, and more preferably equal to or more than 40% by weight, based on the total amount of the liquid encapsulating resin composition. Accordingly, an effect of suppressing clogging is increased when the liquid encapsulating resin composition flows into a gap of the semiconductor device. On the other hand, the content of the inorganic filler is preferably equal to or less than 90% by weight and particularly preferably equal to or less than 85% by weight, based on the total amount of the liquid encapsulating resin composition. Accordingly, an effect of improving the reliability of a semiconductor device is increased.

The liquid encapsulating resin composition of the present invention may contain, if necessary, an additive such as a diluting agent, a pigment, a flame retardant, a leveling agent, a defoaming agent or the like, in addition to the epoxy resin (A), the amine type curing agent (B) and the basic compound (C).

The liquid encapsulating resin composition of the present invention can be produced by dispersing and kneading the aforementioned components, and the additive or the like, with the use of a device such as a planetary mixer, a three roll mill, a heated two roll mill, a grinding machine or the like, and then performing a defoaming treatment in vacuum.

Next, an effect by the liquid encapsulating resin composition of the present invention will be described.

A flux active ingredient of the fluxing agent as the residue has a property of deteriorating the liquid encapsulating resin composition containing the epoxy resin (A) and the amine type curing agent (B), and changing curability. As a result, when the flowability and physical properties of the liquid encapsulating resin composition are changed, and used for encapsulating between the semiconductor element and the substrate, there are problems such that unfilled portions are formed, thus lowering the reliability of the semiconductor device, and the residue of the fluxing agent remains on the periphery of solder bumps even when a no-wash fluxing agent is used, thus lowering the reliability of the semiconductor device from the same reasons as described above in some cases.

The present invention has been achieved to reduce such a phenomenon. With the use of the basic compound (C) for encapsulating between the semiconductor element and the substrate after connecting the semiconductor element and the substrate to each other by solder bumps using a fluxing agent during solder reflow, the residue of the fluxing agent may be dissolved in a liquid encapsulating resin composition. In this way, the present invention can remove the residue of the fluxing agent in order to suppress deterioration of the epoxy resin (A) and the amine type curing agent (B) due to the residue of the fluxing agent. Accordingly, the residue of the fluxing agent may be reduced.

Meanwhile, in the liquid encapsulating resin composition of the present invention, from the viewpoint of removing the residue of the fluxing agent, the pH value of the liquid resin composition is more preferably greater than 7. Accordingly, deterioration of the liquid encapsulating resin composition containing the epoxy resin (A) and the amine type curing agent (B) is further suppressed, and the residue of the fluxing agent may be much reduced. The pH value of the liquid resin composition is more preferably equal to or more than 7.5. Because of this, the residue of the fluxing agent may be further reduced.

A method in order to have the pH value of the liquid encapsulating resin composition of the present invention of greater than 7 is not particularly limited, but the pH may be more suitably achieved by the use of the basic compound (C).

Herein, the pH value indicates a hydrogen ion exponent or a hydrogen ion concentration index. A method of determining the pH value is not particularly limited, but there has generally been used, for example, a method using pH test paper such as litmus test paper or the like, pH indicator, pH electrode, pH sensor or the like. In a process of determining the pH value, a pre-treatment may be performed in the ranges in which the pH value of the liquid encapsulating resin composition is not changed, an additive may be added, or an operation such as heating, cooling or the like may be added.

The residue of the fluxing agent is mainly composed of a carboxylic acid or a carboxylic acid derivative. Examples of the fluxing agent generating such a residue include a fluxing agent mainly composed of rosin, hydrogenated rosin or the like, a fluxing agent having a water soluble resin modified with a carboxylic acid, and the like. The residue of the fluxing agent refers to, for example, the residue of the fluxing agent remained on a connection part of a flip-chip type semiconductor device connected by reflow soldering using the aforementioned fluxing agent, or the residue of the fluxing agent remained on a connection part of a flip-chip type semiconductor device even after carrying out a cleaning step.

Next, the semiconductor device using the aforementioned liquid encapsulating resin composition will be described.

The semiconductor device of the present invention is manufactured, for example, by a flip chip method. According to the flip chip method, first, a semiconductor element having solder bumps and a substrate are connected to each other by solder bumps through the solder reflow using a fluxing agent.

Then, the liquid encapsulating resin composition is filled in a gap between the semiconductor element and the substrate. As a method of filling, a method applying a capillary phenomenon has generally been used. Specifically, there are exemplified a method of applying the aforementioned liquid encapsulating resin composition onto one side of the semiconductor element, and then pouring it into a gap between the semiconductor element and the substrate by a capillary phenomenon; a method of applying the liquid encapsulating resin composition onto both sides of the semiconductor element, and then pouring it into a gap between the semiconductor element and the substrate by a capillary phenomenon; a method of opening a through hole on the center of the semiconductor element, applying the aforementioned liquid encapsulating resin composition onto the periphery of the semiconductor element, and then pouring it into a gap between the semiconductor element and the substrate by a capillary phenomenon, and the like. Also, the total amount may not be applied all at once, and is applied two times. Furthermore, potting, printing or the like may also be used.

Next, the filled liquid encapsulating resin composition is cured. The curing conditions are not particularly limited, and the liquid encapsulating resin composition is cured by heating, for example, in a temperature range of equal to or more than 100 degrees centigrade and equal to or less than 170 degrees centigrade for equal to or more than 1 hour and equal to or less than 12 hours. Furthermore, it may be cured by heating while changing the temperature step by step such that it is heated, for example, at 100 degrees centigrade for 1 hour, and then continuously heating at 150 degrees centigrade for 2 hours.

In this manner, a semiconductor device can be obtained by encapsulating a gap between the semiconductor element and the substrate with a cured product of the liquid encapsulating resin composition.

In the semiconductor device obtained herein, the residue of the fluxing agent is much reduced by the use of the aforementioned liquid encapsulating resin composition. Accordingly, the reliability of the semiconductor device is much improved.

Examples of such a semiconductor device include a flip-chip type semiconductor device, a cavity-down type ball grid array (BGA), a package on package (POP) type ball grid array (BGA), a tape automated bonding (TAB) type ball grid array (BGA), a chip scale package (CSP) and the like.

Specifically, a method of manufacturing a semiconductor device includes applying a fluxing agent onto solder bumps arranged in a semiconductor element or other body for temporarily connecting the semiconductor element and the other body; soldering the aforementioned temporarily connected semiconductor element and other body through solder reflow; and applying the liquid encapsulating resin composition according to the present invention to fill between the semiconductor element and other body. The other body herein is not particularly limited so long as a semiconductor element is mounted thereon, and examples include a circuit board, a flexible circuit board and the like.

### EXAMPLES

The present invention is now illustrated in detail below with reference to Examples and Comparative Examples. However, the present invention is not restricted to these Examples.

### Example 1-1

### 1. Production of Liquid Encapsulating Resin Composition

23.9% by weight of EXA-830LVP (a product of DIC Corporation) as the epoxy resin (A), 14.08% by weight of Kayhard AA (a product of Nippon Kayaku Co., Ltd.) as the amine type curing agent (B), 0.02% by weight of 1,8-diazabicyclo(5,4,0)undecene-7 (hereinafter referred to as DBU) as the basic compound (C), and 62.0% by weight of Admafine SO-E3 (a product of Admatechs Co., Ltd.) as the inorganic filler were kneaded and dispersed using a three roll mill, and then defoamed in vacuum, whereby a liquid encapsulating resin composition was obtained. Incidentally, the epoxy resin (A) and DBU were mixed at room temperature in advance and then allowed to stand overnight prior to use.

### 2. Manufacture of Semiconductor Device

A 15-mm square (number of bumps: 3,872) semiconductor element having solder bumps with a bump size of 100 μm and a bump interval of 200 μm, and a BT substrate (a bismaleimide triazine substrate, connecting pad: gold plated surface) were heated at 260 degrees centigrade using a rosin type flux (Kester 6502, commercially available from Kester), whereby solders were melt-bonded (a gap the between semiconductor element and the BT substrate: 80 μm). The aforementioned liquid encapsulating resin composition was filled in a gap between the bonded semiconductor element and the BT substrate at 110 degrees centigrade, and cured at 150 degrees centigrade for 2 hours for encapsulating, whereby a semiconductor device was obtained.

### Example 1-2

A liquid encapsulating resin composition and a semiconductor device were manufactured in the same manner as in Example 1-1, except that DBU-phenol salt (U-CAT SA1, commercially available from San-Apro Ltd.) was used instead of DBU.

### Example 1-3

A liquid encapsulating resin composition and a semiconductor device were manufactured in the same manner as in Example 1-1, except that 1,5-diazabicyclo(4,3,0)nonene-5 (hereinafter referred to as DBN) was used instead of DBU.

### Example 1-4

A liquid encapsulating resin composition and a semiconductor device were manufactured in the same manner as in Example 1-1, except that the amount of DBU combined was decreased and the total combinations were changed to the following.

23.9% by weight of EXA-830LVP (a product of DIC Corporation) as the epoxy resin (A), 14.09% by weight of Kayhard AA (a product of Nippon Kayaku Co., Ltd.) as the amine type curing agent (B), 0.01% by weight of DBU, and 62.0% by weight of Admafine SO-E3 (a product of Admatechs Co., Ltd.) as the inorganic filler were kneaded and dispersed using a three roll mill, and then defoamed in vacuum, whereby a liquid encapsulating resin composition was obtained. Incidentally, the epoxy resin (A) and DBU were mixed at room temperature in advance and then allowed to stand overnight prior to use.

### Example 1-5

A liquid encapsulating resin composition and a semiconductor device were manufactured in the same manner as in Example 1-1, except that the amount of DBU combined was increased and the total combinations were changed to the following.

23.9% by weight of EXA-830LVP (a product of DIC Corporation) as the epoxy resin (A), 13.9% by weight of Kayhard AA (a product of Nippon Kayaku Co., Ltd.) as the amine type curing agent (B), 0.2% by weight of DBU as the basic compound (C), and 62.0% by weight of Admafine SO-E3 (a product of Admatechs Co., Ltd.) as the inorganic filler were kneaded and dispersed using a three roll mill, and then defoamed in vacuum, whereby a liquid encapsulating resin composition was obtained. Incidentally, the epoxy resin (A) and DBU were mixed at room temperature in advance and then allowed to stand overnight prior to use.

### Example 1-6

Evaluation was carried out in the same manner as in Example 1-1, except that a semiconductor device having solder bumps (bump size: 100 μm, bump interval: 200 μm) mounted on the other body, a substrate, was manufactured.

### Example 1-7

Evaluation was carried out in the same manner as in Example 1-1, except that a semiconductor element and a substrate were heated at 260 degrees centigrade using a rosin type flux (Kester 6502, commercially available from Kester) to melt-bond solders, and then immersed in a flux cleaning agent (Markless ST-100) at 40 degrees centigrade for 2 hours for cleaning and dried, and then the above-mentioned liquid encapsulating resin composition was filled to manufacture a semiconductor device.

### Example 1-8

A liquid encapsulating resin composition and a semiconductor device were manufactured in the same manner as in Example 1-1, except that DBU-phenol salt (U-CAT SA1, commercially available from San-Apro Ltd.) was used instead of DBU in Example 1-1, and the epoxy resin (A) and DBU-phenol salt were not mixed at room temperature in advance prior to use.

### Example 1-9

A liquid encapsulating resin composition and a semiconductor device were manufactured in the same manner as in Example 1-1, except that DBU-phenol salt (U-CATSA1, commercially available from San-Apro Ltd.) was used instead of DBU in Example 1-1, and the epoxy resin (A) and DBU-phenol salt were mixed at room temperature in advance and then allowed to stand for 1 hour prior to use.

### Comparative Example 1-1

A liquid encapsulating resin composition and a semiconductor device were manufactured in the same manner as in Example 1-1, except that the total combinations were changed to the following without using DBU.

23.9% by weight of EXA-830LVP (a product of DIC Corporation) as the epoxy resin (A), 14.1% by weight of Kayhard AA (a product of Nippon Kayaku Co., Ltd.) as the amine type curing agent (B), and 62.0% by weight of Admafine SO-E3 (a product of Admatechs Co., Ltd.) as the inorganic filler were kneaded and dispersed using a three roll mill, and then defoamed in vacuum, whereby a liquid encapsulating resin composition was obtained.

### Example 2-1

### 1. Production of Liquid Encapsulating Resin

### Composition

23.9% by weight of a bisphenol F type epoxy resin (EXA-830LVP, commercially available from DIC Corporation) as the epoxy resin (A), 14.08% by weight of an aromatic amine curing agent (Kayhard AA, commercially available from Nippon Kayaku Co., Ltd.) as the amine type curing agent (B), 0.02% by weight of 1,8-diazabicyclo(5,4,0)undecene-7 (hereinafter referred to as DBU) as the basic compound (C), and 62.0% by weight of spherical silica (Admafine SO-E3, commercially available from Admatechs Co., Ltd.) as the inorganic filler were kneaded and dispersed using a three roll mill, and then defoamed in vacuum, whereby a liquid encapsulating resin composition was obtained.

Incidentally, the amine type curing agent (B) and DBU of the basic compound (C) were mixed at room temperature in advance and then allowed to stand overnight prior to use.

The pH value of the obtained liquid encapsulating resin composition was measured in the following manner. 0.05 ml of the obtained liquid encapsulating resin composition was put on a sensor of a compact pH meter B-211, commercially available from Horiba Ltd., which was previously calibrated using a calibration solution, and about 0.1 ml of pure water was added from the top of the sensor to give a specimen. Furthermore, the pH value was measured after standing the sensor until a display of the sensor indicated that the pH value was stabilized by tilting the sensor so as to cover the entire surface with the specimen and closing a lid of the sensor. The pH value of the specimen was 10.

### 2. Manufacture of Semiconductor Device

A 15-mm square (number of bumps: 3,872) semiconductor element having solder bumps with a bump size of 100 μm and a bump interval of 200 μm, and a BT substrate (a bismaleimide triazine substrate, connecting pad: gold plated surface) were heated at 260 degrees centigrade using a rosin type flux (Kester 6502, commercially available from Kester), whereby solders were melt-bonded (a gap between the semiconductor element and the BT substrate: 80 μm). The aforementioned liquid encapsulating resin composition was filled in a gap between the bonded semiconductor element and the BT substrate at 110 degrees centigrade, and cured at 150 degrees centigrade for 2 hours for encapsulating, whereby a semiconductor device was obtained.

### Example 2-2

A liquid encapsulating resin composition and a semiconductor device were manufactured in the same manner as in Example 2-1, except that DBU-phenol salt (U-CAT SA1, commercially available from San-Apro Ltd.) was used instead of DBU. The pH value of the liquid encapsulating resin composition was 8.

### Example 2-3

A liquid encapsulating resin composition and a semiconductor device were manufactured in the same manner as in Example 2-1, except that 1,5-diazabicyclo(4,3,0)nonene-5 (hereinafter referred to as DBN) was used instead of DBU. The pH value of the liquid encapsulating resin composition was 11.

### Example 2-4

A liquid encapsulating resin composition and a semiconductor device were manufactured in the same manner as in Example 2-1, except that the amount of DBU combined was decreased and the total combinations were changed to the following.

23.9% by weight of a bisphenol F type epoxy resin (EXA-830LVP, commercially available from DIC Corporation) as the epoxy resin (A), 14.09% by weight of an aromatic amine curing agent (Kayhard AA, commercially available from Nippon Kayaku Co., Ltd.) as the amine type curing agent (B), 0.01% by weight of DBU as the basic compound (C), and 62.0% by weight of spherical silica (Admafine SO-E3, commercially available from Admatechs Co., Ltd.) were kneaded and dispersed using a three roll mill, and then defoamed in vacuum, whereby a liquid encapsulating resin composition was obtained.

Incidentally, the amine type curing agent (B) and DBU of the basic compound (C) were mixed at room temperature in advance and then allowed to stand overnight prior to use. The pH value of the liquid encapsulating resin composition was 9.

### Example 2-5

A liquid encapsulating resin composition and a semiconductor device were manufactured in the same manner as in Example 2-1, except that the amount of DBU combined was increased and the total combinations were changed to the following.

23.9% by weight of a bisphenol F type epoxy resin (EXA-830LVP, commercially available from DIC Corporation) as the epoxy resin (A), 13.9% by weight of an aromatic amine curing agent (Kayhard AA, commercially available from Nippon Kayaku Co., Ltd.) as the amine type curing agent (B), 0.2% by weight of DBU as the basic compound (C), and 62.0% by weight of spherical silica (Admafine SO-E3, commercially available from Admatechs Co., Ltd.) as the inorganic filler were kneaded and dispersed using a three roll mill, and then defoamed in vacuum, whereby a liquid encapsulating resin composition was obtained.

Incidentally, the amine type curing agent (B) and DBU of the basic compound (C) were mixed at room temperature in advance and then allowed to stand overnight prior to use. The pH value of the liquid encapsulating resin composition was 11.

### Example 2-6

A liquid encapsulating resin composition and a semiconductor device were manufactured in the same manner as in Example 2-1, except that the amount of DBU combined was increased and the total combinations were changed to the following.

23.84% by weight of a bisphenol F type epoxy resin (EXA-830LVP, commercially available from DIC Corporation) as the epoxy resin (A), 13.86% by weight of an aromatic amine curing agent (Kayhard AA, commercially available from Nippon Kayaku Co., Ltd.) as the amine type curing agent (B), 0.3% by weight of DBU as the basic compound (C), and 62.0% by weight of spherical silica (Admafine SO-E3, commercially available from Admatechs Co., Ltd.) as the inorganic filler were kneaded and dispersed using a three roll mill, and then defoamed in vacuum, whereby a liquid encapsulating resin composition was obtained.

Incidentally, the amine type curing agent (B) and DBU of the basic compound (C) were mixed at room temperature in advance and then allowed to stand overnight prior to use. The pH value of the liquid encapsulating resin composition was 12.

### Example 2-7

A liquid encapsulating resin composition and a semiconductor device were manufactured in the same manner as in Example 2-4, except that DBU-phenol salt (U-CAT SA1, commercially available from San-Apro Ltd.) was used instead of DBU. The pH value of the liquid encapsulating resin composition was 7.5.

### Example 2-8

Evaluation was carried out in the same manner as in Example 2-1, except that a semiconductor device having solder bumps (bump size: 100 μm, bump interval: 200 μm) mounted on the other body, a substrate, was manufactured. The pH value of the liquid encapsulating resin composition was 10.

### Example 2-9

Evaluation was carried out in the same manner as in Example 2-1, except that a semiconductor element and a substrate were heated at 260 degrees centigrade using a rosin type flux (Kester 6502, commercially available from Kester) to melt-bond solders, and then immersed in a flux cleaning agent (Markless ST-100) at 40 degrees centigrade for 2 hours for cleaning and dried, and then the above-mentioned liquid encapsulating resin composition was filled to manufacture a semiconductor device. The pH value of the liquid encapsulating resin composition was 10.

### Example 2-10

A liquid encapsulating resin composition and a semiconductor device were manufactured in the same manner as in Example 2-1, except that DBU-phenol salt (U-CAT SA1, commercially available from San-Apro Ltd.) was used instead of DBU in Example 2-1, and the amine type curing agent (B) and DBU-phenol salt of the basic compound (C) were not mixed at room temperature in advance prior to use. The pH value of the liquid encapsulating resin composition was 8.

### Example 2-11

A liquid encapsulating resin composition and a semiconductor device were manufactured in the same manner as in Example 2-1, except that DBU-phenol salt (U-CAT SA1, commercially available from San-Apro Ltd.) was used instead of DBU in Example 2-1, and the amine type curing agent (B) and DBU-phenol salt of the basic compound (C) were mixed at room temperature in advance and then allowed to stand for 1 hour prior to use. The pH value of the liquid encapsulating resin composition was 8.

### Comparative Example 2-1

A liquid encapsulating resin composition and a semiconductor device were manufactured in the same manner as in Example 2-1, except that the total combinations were changed to the following without using DBU.

23.9% by weight of a bisphenol F type epoxy resin (EXA-830LVP, commercially available from DIC Corporation) as the epoxy resin (A), 14.1% by weight of an aromatic amine curing agent (Kayhard AA, commercially available from Nippon Kayaku Co., Ltd.) as the amine type curing agent (B), and 62.0% by weight of spherical silica (Admafine SO-E3, commercially available from Admatechs Co., Ltd.) as the inorganic filler were kneaded and dispersed using a three roll mill, and then defoamed in vacuum, whereby a liquid encapsulating resin composition was obtained. The pH value of the liquid encapsulating resin composition was 7.

Evaluation Items

The obtained liquid encapsulating resin composition and semiconductor device were evaluated in the following manner. The obtained results are shown in Tables 1 and 2.

1. Removal Performance of Fluxing Agent Residue

Removal performance of the fluxing agent residue was evaluated in the following manner.

A 15-mm square (number of bumps: 3,872) semiconductor element having solder bumps with a bump size of 100 μm and a bump interval of 200 μm was put on a slide glass, and heated at 260 degrees centigrade using a rosin type flux (Kester 6502, commercially available from Kester), whereby solders were melted to bond the semiconductor element and the slide glass. Attachment of the residue of the fluxing agent before encapsulating was observed from a back surface of the slide glass to count the total number of bumps observed with the residue attached thereto, and then the aforementioned liquid encapsulating resin composition was filled in a gap between the semiconductor element and the slide glass at 110 degrees centigrade, and cured at 150 degrees centigrade for 2 hours for encapsulating. Thereafter, among bumps where attachment of the residue of the fluxing agent before encapsulating was observed, the number of bumps where attachment of the residue of the fluxing agent after encapsulating was not observed was counted. The residue of the fluxing agent was calculated according to the following equation.

Residue of fluxing agent=Number of bumps where attachment of the fluxing agent residue after encapsulating was not observed among bumps where attachment of the fluxing agent residue before encapsulating was observed/Number of bumps where attachment of the fluxing agent residue before encapsulating was observed.

The respective symbols in Tables are as defined below.

AA: Fluxing agent residue of equal to or more than 75% and equal to or less than 100%.

BB: Fluxing agent residue of equal to or more than 50% and less than 75%.

CC: Fluxing agent residue of equal to or more than 25% and less than 50%.

DD: Fluxing agent residue of equal to or more than 0% and less than 25%.

2. Connection Reliability

For the connection reliability, insulation resistance (while applying 5V for 30 seconds) after subjecting the semiconductor device obtained according to the above Examples and Comparative Examples to a voltage, high temperature and high humidity treatment (temperature: 135 degrees centigrade, humidity: 85%, applied voltage: 5V, duration: 250 hours) was measured and evaluated.

The respective symbols in Tables are as defined below.

AA: Insulation resistance of equal to or more than 1×10¹⁰Ω.

BB: Insulation resistance of equal to or more than 1×10⁹Ω and less than 1×10¹⁰Ω.

CC: Insulation resistance of equal to or more than 1×10⁷Ω and less than 1×10⁹Ω.

DD: Insulation resistance of less than 1×107 Ω.

3. Flowability

A glass plate (upper) and a glass plate (lower) of 18 mm×18 mm were laminated so as to open an interval of 70±10 μm, whereby a glass cell having a parallel plane with a gap was prepared. The glass cell was placed on a hot plate, and allowed to stand for five minutes while controlling a temperature such that an upper surface temperature of the glass plate (upper) became 110±1 degrees centigrade. Thereafter, 0.05 to 0.1 mL of the liquid encapsulating resin composition which was allowed to stand at room temperature for 24 hours was applied onto one side of the glass cell, and 18-mm flowing time (flow time) was measured.

The respective symbols in Tables are as defined below.

AA: Flow time of equal to or more than 100 seconds and less than 150 seconds.

BB: Flow time of equal to or more than 150 seconds and less than 250 seconds.

CC: Flow time of equal to or more than 250 seconds and less than 300 seconds.

DD: Flow time of equal to or more than 300 seconds.

TABLE 1

| | Exam- | Exam- | Exam- | | |
|---|---|---|---|---|---|
| | ple 1-1 | ple 1-2 | ple 1-3 | Example 1-4 | Example 1-5 |
| Removal | AA | BB | AA | BB | AA |
| performance | | | | | |
| of residue | | | | | |
| Connection | AA | AA | AA | BB | AA |
| reliability | | | | | |
| Flowability | AA | AA | AA | AA | BB |
| | Exam- | Exam- | Exam- | | Comparative |
| | ple 1-6 | ple 1-7 | ple 1-8 | Example 1-9 | Example 1-1 |
| Removal | AA | AA | BB | AA | DD |
| performance | | | | | |
| of residue | | | | | |
| Connection | AA | AA | BB | AA | CC |
| reliability | | | | | |
| Flowability | AA | AA | AA | BB | BB |

TABLE 2

| | Example | Example | Example | Example | Example | Example |
|---|---|---|---|---|---|---|
| | 2-1 | 2-2 | 2-3 | 2-4 | 2-5 | 2-6 |
| pH value | 10 | 8 | 11 | 9 | 11 | 12 |
| Removal | AA | BB | AA | BB | AA | AA |
| performance of | | | | | | |
| residue | | | | | | |
| Connection | AA | AA | AA | BB | AA | AA |
| reliability | | | | | | |
| Flowability | AA | AA | AA | AA | BB | BB |
| | Example | Example | Example | Example | Example | Comparative |
| | 2-7 | 2-8 | 2-9 | 2-10 | 2-11 | Example 2-1 |
| pH value | 7.5 | 10 | 10 | 8 | 8 | 7 |
| Removal | BB | AA | AA | BB | BB | DD |
| performance of | | | | | | |
| residue | | | | | | |
| Connection | BB | AA | AA | BB | BB | CC |
| reliability | | | | | | |
| Flowability | AA | AA | AA | BB | BB | BB |

### INDUSTRIAL APPLICABILITY

The present invention can be used to obtain a liquid encapsulating resin composition which improves the reliability of a semiconductor device manufactured through a step of using a fluxing agent, and a semiconductor device using the liquid encapsulating resin composition.

The present application claims priority based on Japanese patent application No. 2009-095382 filed on Apr. 10, 2009, and incorporates herein the entire disclosure thereof by reference.

1. A liquid encapsulating resin composition containing;
an epoxy resin (A),
an amine type curing agent (B) and
a basic compound (C),
wherein, in case that the liquid encapsulating resin composition is filled between a semiconductor element and a substrate connected to each other by solder bumps, the residue of a fluxing agent used for forming the solder bump connection is removed.

2. The liquid encapsulating resin composition according to claim 1, wherein the pH value of said liquid encapsulating resin composition is greater than 7.

3. The liquid encapsulating resin composition according to claim 1, wherein said basic compound (C) is at least one kind among 1,8-diazabicyclo(5.4.0)undecene-7,1,5-diazabicyclo(4.3.0)nonene-5 and a salt thereof.

4. The liquid encapsulating resin composition according to claim 1, wherein the content of said basic compound (C) is equal to or more than 0.005% by weight and equal to or less than 0.3% by weight, based on the total amount of said liquid encapsulating resin composition.

5. The liquid encapsulating resin composition according to claim 1, wherein said basic compound (C) and said amine type curing agent (B) are mixed in advance, and then said epoxy resin (A) is mixed thereto.

6. The liquid encapsulating resin composition according to claim 1, wherein said basic compound (C) and said epoxy resin (A) are mixed in advance, and then said amine type curing agent (B) is mixed thereto.

7. The liquid encapsulating resin composition according to claim 1, wherein the residue of said fluxing agent is mainly composed of a carboxylic acid or a carboxylic acid derivative.

8. A semiconductor device, wherein a gap between said semiconductor element and said substrate is encapsulated with a cured product of the liquid encapsulating resin composition according to claim 1.

9. A method of manufacturing a semiconductor device comprising:
applying a fluxing agent onto solder bumps arranged in a semiconductor element or other body for temporarily connecting said semiconductor element and said other body;
soldering said temporarily connected semiconductor element and other body through the solder reflow; and
applying the liquid encapsulating resin composition according to claim 1 to fill between said semiconductor element and said other body.
